(19) United States
(12) Patent Application Publication
(10) Pub. No.: US 2012/0090664 A1
(43) Pub. Date: Apr. 19, 2012

(54) PHOTOVOLTAIC DEVICE

(75) Inventors: Kengo Yamaguchi, Tokyo, (JP); Nobuki Yamashita, Tokyo, (JP)

(73) Assignee: MITSUBISHI HEAVY INDUSTRIES, LTD., Minato-ku, Tokyo, (JP)

(21) Appl. No.: 13/378,331

(22) PCT Filed: Jun. 23, 2010
(86) PCT No.: PCT/JP2010/060600

§ 371 Date: Dec. 14, 2011

(30) Foreign Application Priority Data
Nov. 20, 2009 (JP) 2009-265173

(51) Int. Cl. H01L 31/06; H01L 31/18

(52) U.S. Cl. 136/249; 438/98; 257/E31.001

(57) ABSTRACT

A photovoltaic device in which leakage current is suppressed and the conversion efficiency is improved. A photovoltaic device (100) comprising a photovoltaic layer (3) comprising two electric power generation cell layers (91, 92) disposed on a substrate (1), and an intermediate contact layer (5) interposed between the two electric power generation cell layers (91, 92), wherein the intermediate contact layer (5) comprises Ga₂O₃-doped ZnO as the main component and also comprises nitrogen atoms, and the sheet resistance of the intermediate contact layer (5) following exposure to a hydrogen plasma is not less than 1 kΩ/square and not more than 100 kΩ/square.

### TECHNICAL FIELD

The present invention relates to a photovoltaic device, and relates particularly to a thin-film solar cell in which the electric power generation layer is formed by deposition.

### BACKGROUND ART

One known example of a photovoltaic device used in a solar cell that converts the energy from sunlight into electrical energy is a thin-film silicon-based photovoltaic device comprising a photovoltaic layer formed by using a plasma-enhanced CVD method or the like to deposit thin films of a p-type silicon-based semiconductor (p-layer), an i-type silicon-based semiconductor (i-layer) and an n-type silicon-based semiconductor (n-layer) on top of a transparent electrode layer formed on a substrate.

In order to improve the conversion efficiency, namely the electric power generation output, of thin-film silicon-based solar cells, tandem solar cells have been proposed in which the photovoltaic layer is formed by stacking two stages of electric power generation cell layers having different absorption wavelength bands, thereby enabling more efficient absorption of the incident light. In tandem solar cells, an intermediate contact layer is frequently inserted between the layers of the first electric power generation cell and the layers of the second electric power generation cell that function as the photovoltaic layer, for the purposes of inhibiting the mutual diffusion of dopants between the cell layers and adjusting the light intensity distribution.

Zinc oxide (ZnO), which has a refractive index of approximately 2.0 that is significantly lower than that of silicon, and exhibits excellent levels of plasma resistance and transparency is generally used as the material for the intermediate contact layer. However, the resistivity of zinc oxide deteriorates upon exposure to a hydrogen plasma atmosphere. It is thought that this reduction in the resistivity, namely an increase in the conductivity, is because the hydrogen plasma increases the occurrence of oxygen defects in the ZnO. As a result, in the case of a stacked solar cell module, a leakage current tends to flow from the intermediate contact layer toward the metal electrode in the cell connection portion (namely, a horizontal direction leakage current), resulting in a deterioration in the fill factor. Countermeasures such as adding a laser-processed portion at the connection portion have been used to inhibit this leakage current (shunt component), but providing a new processed portion reduces the effective surface area, and also results in increased costs due to the increase in processing steps.

Patent Literature (PTL) 1 discloses a stacked photovoltaic device in which, by providing a selective reflection layer having a high sheet resistance of not less than 100 kΩ/square and not more than 100 kΩ/square between a first photovoltaic element and a second photovoltaic element, a large photocurrent can be obtained without an accompanying reduction in the electromotive force.

### CITATION LIST

### Patent Literature

{PTL 1} Japanese Unexamined Patent Application, Publication No. 2004-311970 (claim 1, paragraphs [0019], [0029] and [0036])

### SUMMARY OF INVENTION

### Technical Problem

As can be ascertained from paragraph [0054] in PTL 1, the sheet resistance value for the selective reflection layer that is evaluated in PTL 1 refers to a measured value for a sample that has been prepared by depositing the selective reflection layer directly on a substrate, without exposing the surface of the selective reflection layer to a hydrogen plasma. In other words, in PTL 1, the reduction in resistance caused by exposure of the zinc oxide layer to a hydrogen plasma is not considered. If, as in PTL 1, the resistivity following plasma treatment is not controlled, then the leakage current cannot be effectively suppressed.

The present invention has been developed in light of the above circumstances, and provides a photovoltaic device in which, by setting the conductivity following exposure to a hydrogen plasma within an appropriate range, leakage current is suppressed and the conversion efficiency is improved.

### Solution to Problem

In order to address the issues described above, the present invention provides a photovoltaic device comprising a photovoltaic layer comprising two electric power generation cell layers disposed on a substrate, and an intermediate contact layer interposed between the two electric power generation cell layers, wherein the intermediate contact layer comprises Ga₂O₃-doped ZnO as the main component and also comprises nitrogen atoms, and the sheet resistance of the intermediate contact layer following exposure to a hydrogen plasma is not less than 1 kΩ/square and not more than 100 kΩ/square.

In the present invention, the intermediate contact layer may comprise Ga₂O₃-doped Zn₁₋ₓMgₓO₂ (0.096≦x≦0.183) as the main component.

A nitrogen atom-containing film comprising GZO as the main component exhibits a higher resistivity following exposure to a hydrogen plasma than a film containing no nitrogen atoms. In other words, by adding nitrogen atoms to a film comprising GZO as the main component, the conductivity (resistivity) of the intermediate contact layer can be controlled so as to satisfy an appropriate range. In order to suppress leakage current at the cell connection portion while maintaining favorable contact properties, the sheet resistance of the intermediate contact layer should be at least 1 kΩ/square. On the other hand, in order to ensure favorable electrical conductivity through the film in the vertical direction, reducing the series resistance is essential, and therefore the sheet resistance of the intermediate contact layer must be not more than 100 kΩ/square.

In the invention described above, the intermediate contact layer preferably comprises a first layer comprising Ga₂O₃-doped ZnO as the main component, and a second layer provided on the surface of the first layer opposite the substrate-side surface, comprising Ga₂O₃-doped ZnO as the main component and also comprising nitrogen atoms, wherein the sheet resistance of the second cell layer following exposure to a hydrogen plasma is not less than 1 kΩ/square and not more than 100 kΩ/square.

In this case, the second layer may comprise Ga₂O₃-doped Zn₁₋ₓMgₓO₂ (0.096≦x≦0.183) as the main component.

In this manner, leakage current at the cell connection portion can also be suppressed by forming the intermediate contact layer as a two-layer structure in which the layer on the opposite side to the substrate, namely the layer that contacts the electric power generation cell layer provided on top of the intermediate contact layer, is a nitrogen atom-containing film comprising GZO as the main component.

### Advantageous Effects of Invention

By providing a film comprising GZO as the main component and also comprising nitrogen as the intermediate contact layer, the sheet resistance of the intermediate contact layer following hydrogen plasma treatment can be controlled. As a result, the leakage current can be suppressed without providing a new processed portion, meaning a high-efficiency photovoltaic device can be obtained.

### BRIEF DESCRIPTION OF DRAWINGS

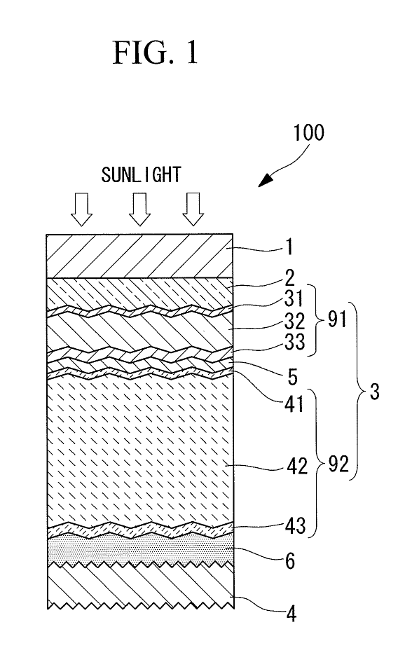

{FIG. 1} A schematic view illustrating the structure of a photovoltaic device according to a first embodiment.

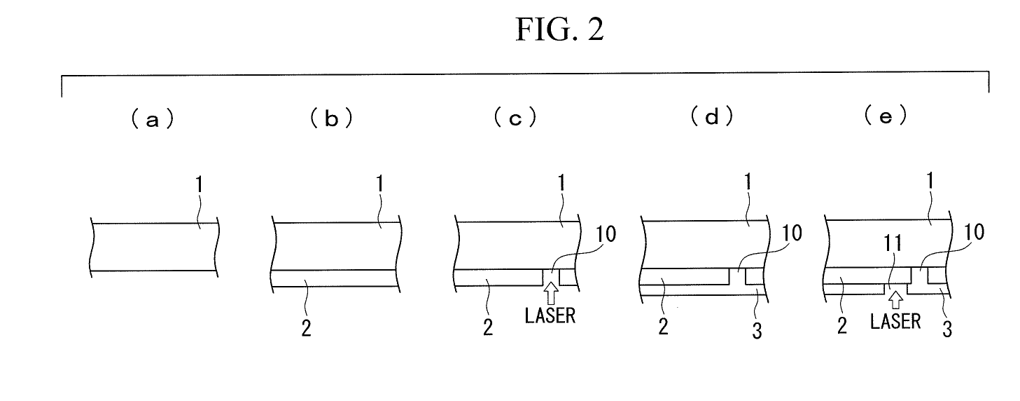

{FIG. 2} A schematic illustration describing one embodiment for producing a solar cell panel as a photovoltaic device according to the first embodiment.

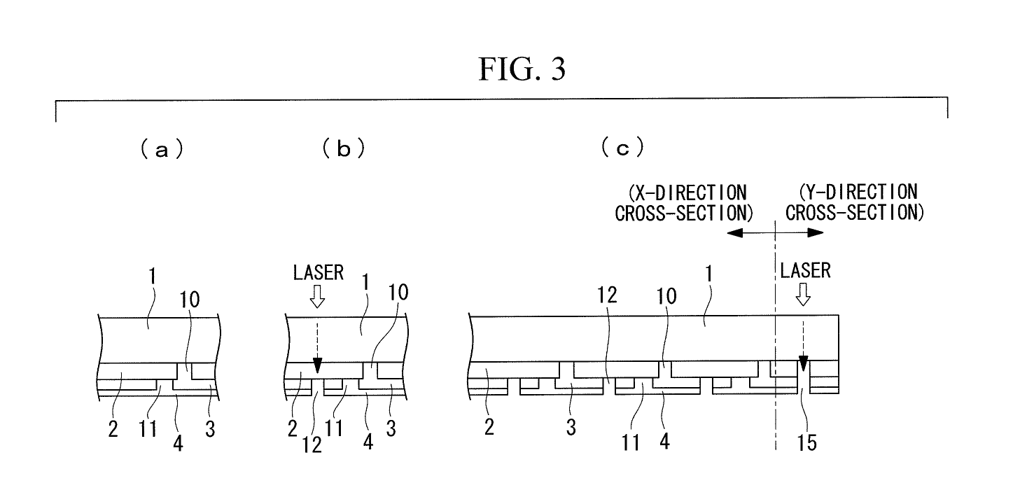

{FIG. 3} A schematic illustration describing one embodiment for producing a solar cell panel as a photovoltaic device according to the first embodiment.

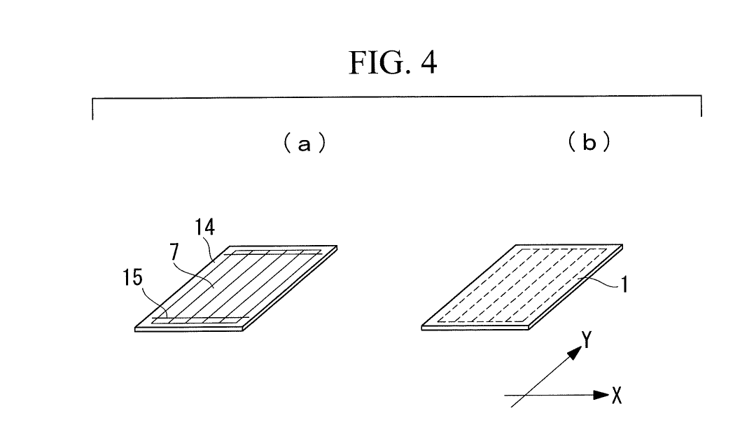

{FIG. 4} A schematic illustration describing one embodiment for producing a solar cell panel as a photovoltaic device according to the first embodiment.

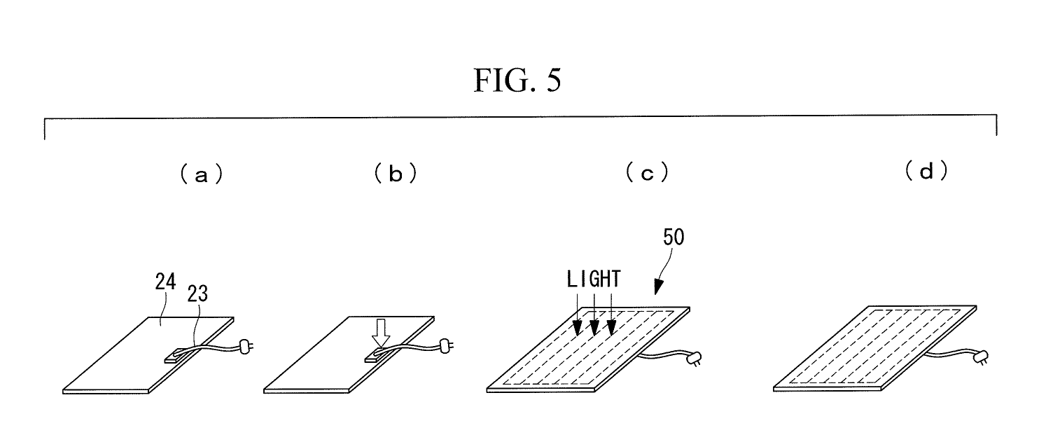

{FIG. 5} A schematic illustration describing one embodiment for producing a solar cell panel as a photovoltaic device according to the first embodiment.

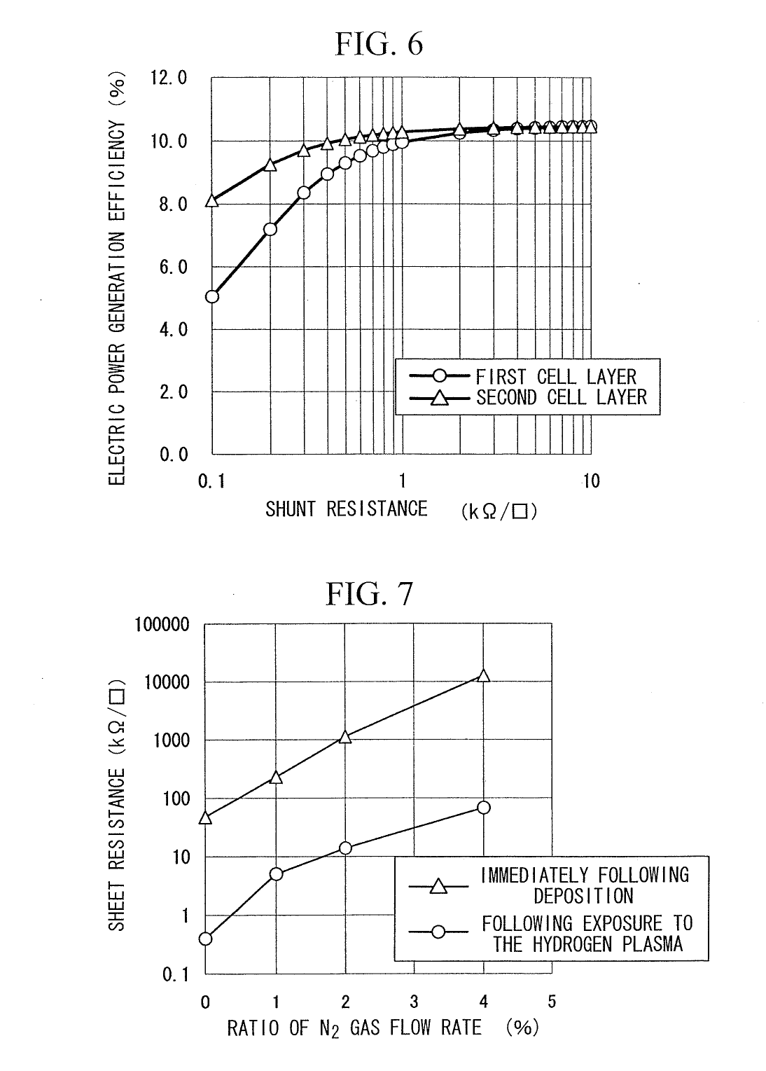

{FIG. 6} A graph illustrating the relationship between the shunt resistance at the connection portion and the cell performance.

{FIG. 7} A graph illustrating the relationship between the amount of added N₂ gas during GZO deposition and the GZO film sheet resistance.

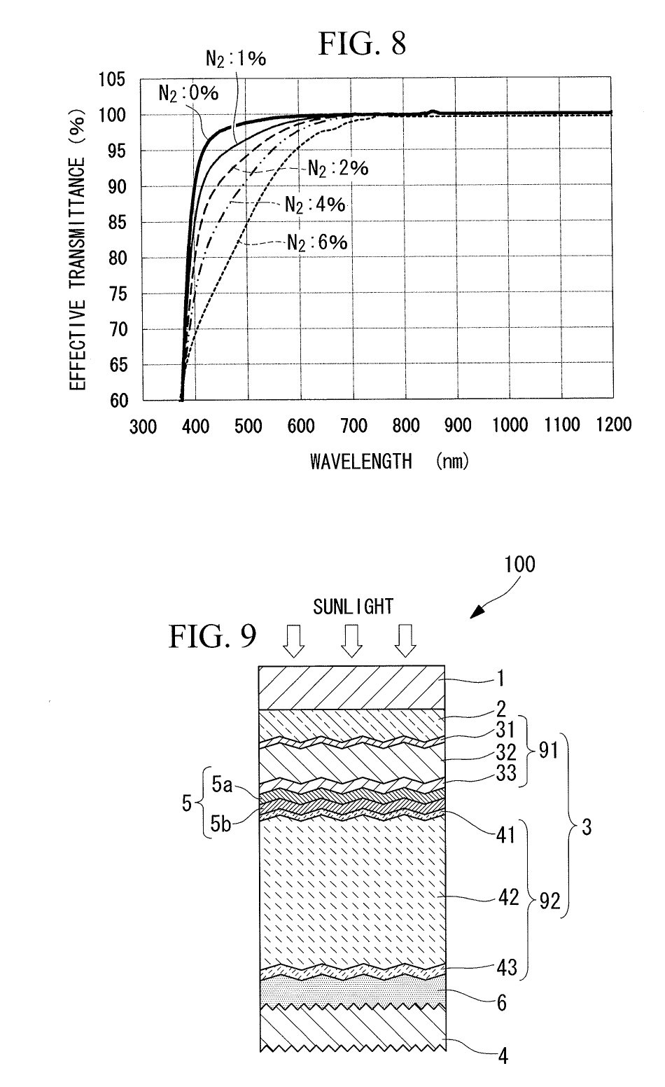

{FIG. 8} A graph illustrating the optical properties of GZO films prepared using different amounts of added N₂ gas during deposition.

{FIG. 9} A schematic view illustrating the structure of a photovoltaic device according to a second embodiment.

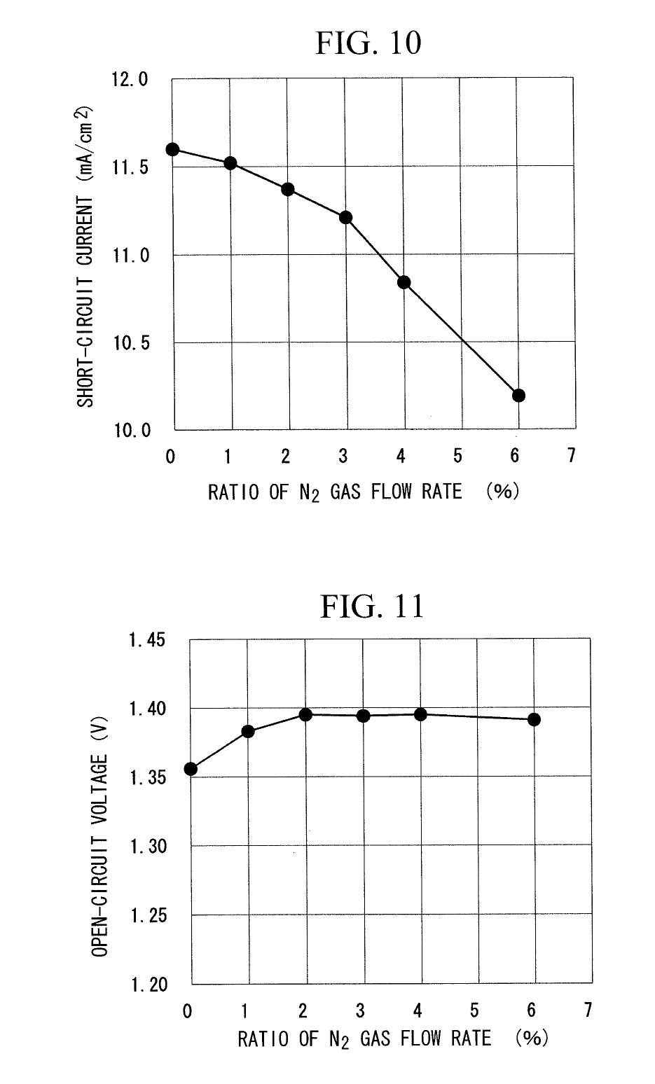

{FIG. 10} A graph illustrating the relationship between the amount of added N₂ gas during deposition of the intermediate contact layer and the short-circuit current.

{FIG. 11} A graph illustrating the relationship between the amount of added N₂ gas during deposition of the intermediate contact layer and the open-circuit voltage.

{FIG. 12} A graph illustrating the relationship between the amount of added N₂ gas during deposition of the intermediate contact layer and the fill factor.

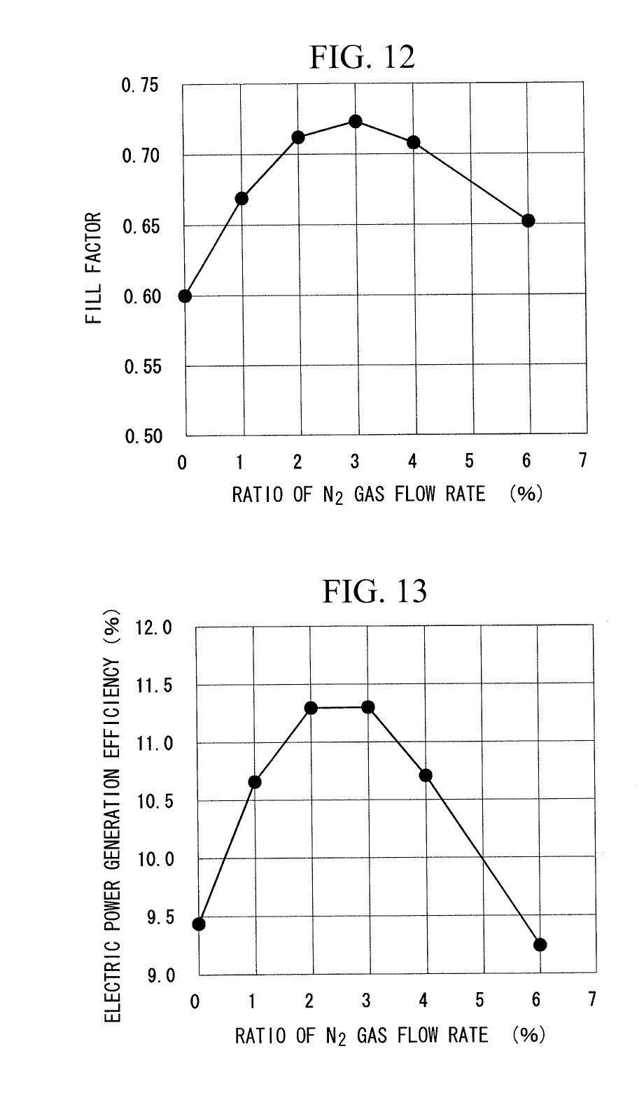

{FIG. 13} A graph illustrating the relationship between the amount of added N₂ gas during deposition of the intermediate contact layer and the electric power generation efficiency.

### DESCRIPTION OF EMBODIMENTS

### First Embodiment

FIG. 1 is a schematic view illustrating the structure of a photovoltaic device of the present invention. The photovoltaic device 100 is a tandem silicon-based solar cell, and comprises a substrate 1, a transparent electrode layer 2, a first cell layer 91 (amorphous silicon-based) and a second cell layer 92 (crystalline silicon-based) that function as a solar cell photovoltaic layer 3, an intermediate contact layer 5, and a back electrode layer 4. Here, the term “silicon-based” is a generic term that includes silicon (Si), silicon carbide (SiC) and silicon germanium (SiGe). Further, the term “crystalline silicon-based” describes a silicon system other than an amorphous silicon system, and includes both microcrystalline silicon systems and polycrystalline silicon systems.

A photovoltaic device according to the first embodiment is described below, using the production steps for a solar cell panel as an example. FIG. 2 to FIG. 5 are schematic views illustrating a process for producing a solar cell panel according to this embodiment.

(1) FIG. 2(a)

A soda float glass substrate (for example with dimensions of 1.4 m×1.1 m×thickness: 3.5 to 4.5 mm) is used as the substrate 1. The edges of the substrate are preferably subjected to corner chamfering or R-face chamfering to prevent damage caused by thermal stress or impacts or the like.

(2) FIG. 2(b)

A transparent conductive film comprising mainly tin oxide (SnO₂) and having a film thickness of approximately not less than 500 nm and not more than 800 nm is deposited as the transparent electrode layer 2, using a thermal CVD apparatus at a temperature of approximately 500° C. During this deposition, a texture comprising suitable asperity is formed on the surface of the transparent conductive film. In addition to the transparent conductive film, the transparent electrode layer 2 may also include an alkali barrier film (not shown in the figure) formed between the substrate 1 and the transparent conductive film. The alkali barrier film is formed using a thermal CVD apparatus at a temperature of approximately 500° C. to deposit a silicon oxide film (SiO₂) having a thickness of 50 nm to 150 nm.

(3) FIG. 2(c)

Subsequently, the substrate 1 is mounted on an X-Y table, and the first harmonic of a YAG laser (1064 nm) is irradiated onto the surface of the transparent conductive film, as shown by the arrow in the figure. The laser power is adjusted to ensure an appropriate process speed, and the transparent conductive film is then moved in a direction perpendicular to the direction of the series connection of the electric power generation cells, thereby causing a relative movement between the substrate 1 and the laser light, and conducting laser etching across a strip having a predetermined width of approximately 6 mm to 15 mm to form a slot 10.

(4) FIG. 2(d)

Using a plasma-enhanced CVD apparatus, a p-layer, an i-layer and an n-layer, each composed of a thin film of amorphous silicon, are deposited as the first cell layer 91. Using SiH₄ gas and H₂ gas as the main raw materials, and under conditions including a reduced pressure atmosphere of not less than 30 Pa and not more than 1,000 Pa and a substrate temperature of approximately 200° C., an amorphous silicon p-layer 31, an amorphous silicon i-layer 32 and an amorphous silicon n-layer 33 are deposited, in that order, on the transparent electrode layer 2, with the p-layer closest to the surface from which incident sunlight enters. The amorphous silicon p-layer 31 comprises mainly amorphous B-doped silicon, and has a thickness of not less than 10 nm and not more than 30 nm. The amorphous silicon i-layer 32 has a thickness of not less than 200 nm and not more than 350 nm. The amorphous silicon n-layer 33 comprises mainly P-doped silicon in which microcrystalline silicon is incorporated within amorphous silicon, and has a thickness of not less than 30 nm and not more than 50 nm. A buffer layer may be provided between the amorphous silicon p-layer 31 and the amorphous silicon i-layer 32 in order to improve the interface properties.

The intermediate contact layer 5, which functions as a semi-reflective film for improving the contact properties and achieving electrical current consistency, is provided between the first cell layer 91 and the second cell layer 92. The intermediate contact layer of the present embodiment comprises Ga₂O₃-doped ZnO (GZO) as the main component, and also contains nitrogen atoms. The thickness of the intermediate contact layer of the present embodiment is not less than 20 nm and not more than 100 nm.

In the present embodiment, an RF magnetron sputtering method or a DC sputtering method can be used as the method for depositing the intermediate contact layer. In the case where deposition is performed using an RF magnetron sputtering method, the deposition conditions include a Ga₂O₃-doped ZnO sintered compact as the target, Ar gas, O₂ gas and N₂ gas as the raw material gases, a pressure of 0.13 to 0.67 Pa, RF power of 1.1 to 4.4 W/cm², and a substrate temperature of 120° C.

The intermediate contact layer is exposed to a hydrogen plasma during deposition of the second cell layer 92 in a subsequent stage. As a result of this exposure, the sheet resistance of the intermediate contact layer decreases to a level less than that observed at the time of deposition of the intermediate contact layer. In the present embodiment, the sheet resistance of the intermediate contact layer 5 following exposure to the hydrogen plasma is typically not less than 1 kΩ/square and not more than 100 kΩ/square, and is preferably not less than 10 kΩ/square and not more than 100 kΩ/square.

FIG. 6 illustrates the results of calculating the shunt resistance at the connection portion and the cell performance using an equivalent circuit corresponding with the module structure of the present embodiment. In the figure, the horizontal axis represents the shunt resistance and the vertical axis represents the electric power generation efficiency of the module. The electric power generation efficiency deteriorates rapidly when the shunt resistance falls below 1 kΩ/square. A reduction in the shunt resistance in the first cell layer (amorphous silicon-based) has a particular large effect on the electric power generation efficiency of the module. It is evident that if the shunt resistance is at least 1 kΩ/square, and particularly 10 kΩ/square or greater, then the effect of the shunt resistance on the module performance disappears almost entirely.

FIG. 7 illustrates the relationship between the amount of added N₂ gas during GZO deposition and the GZO film sheet resistance. In this figure, the horizontal axis represents the ratio of the N₂ gas flow rate relative to the Ar gas flow rate, and the vertical axis represents the sheet resistance of the GZO film. Deposition of the GZO film was performed under conditions including a glass substrate, a 0.5 mass % Ga₂O₃-doped ZnO sintered compact as the target, a ratio of the O₂ gas flow rate relative to the Ar gas flow rate of 1%, a pressure of 0.2 Pa, RF power of 4.4 W/cm², a substrate temperature of 120° C., and a target film thickness of 80 nm. The hydrogen plasma treatment conditions were set to 40 Pa and 0.5 W/cm². The sheet resistance of the GZO film following exposure to the hydrogen plasma decreased by 2 to 3 orders of magnitude compared with the sheet resistance immediately following deposition. For the deposition conditions under which the results of FIG. 7 were obtained, the GZO film sheet resistance following exposure to the hydrogen plasma fell within a range from 1 kΩ/square to 100 kΩ/square when the ratio of the N₂ gas flow rate relative to the Ar gas flow rate was not less than 1% and not more than 4%, and fell within a range from 10 kΩ/square to 100 kΩ/square when the ratio was not less than 2% and not more than 4%.

The nitrogen atom concentration within the GZO film can be controlled by altering the flow rate ratio (partial pressure ratio) of N₂ gas relative to Ar gas. As the amount of N₂ gas is increased, the nitrogen atom concentration within the GZO film also tends to increase. Under the deposition conditions mentioned above, 1% of added N₂ gas yields 0.25 atomic % of nitrogen atoms within the GZO film, 2% of added N₂ gas yields 0.5 atomic % of nitrogen atoms, and 4% of added N₂ gas yields 1 atomic % of nitrogen atoms.

FIG. 8 illustrates the optical properties of GZO films prepared using different amounts of added N₂ gas during deposition. In the figure, the horizontal axis represents the wavelength and the vertical axis represents the effective transmittance. Adding nitrogen atoms to the GZO film reduces the transmittance in the visible light region at wavelengths of 700 nm or shorter. Under the deposition conditions mentioned above, provided the N₂ gas ratio is within a range from 1% to 4%, light absorption loss can be suppressed.

The sheet resistance of the GZO film as the intermediate contact layer also varies in accordance with factors such as the amount of Ga₂O₃ doping and the oxygen partial pressure within the deposition atmosphere. Accordingly, the relationship between the amount of added N₂ gas or the N₂ gas partial pressure and the sheet resistance following exposure to a hydrogen plasma is preferably determined for various deposition conditions such as the amount of Ga₂O₃ doping and the oxygen partial pressure within the deposition atmosphere.

Further, in the present embodiment, the intermediate contact layer 5 may comprise a Ga₂O₃-doped compound represented by Zn₁₋ₓMgₓO₂ as the main component. In order to satisfy the above-mentioned sheet resistance following exposure to a hydrogen plasma, x must satisfy 0.096≦x≦0.183 in the above composition. In order to achieve deposition of Ga₂O₃-doped Zn₁₋ₓMgₓO₂, a Ga₂O₃-doped ZnO—MgO mixed target (MgO ratio: 5 to 10 mass %) may be used.

Subsequently, using a plasma-enhanced CVD apparatus, and under conditions including a reduced pressure atmosphere of not more than 3,000 Pa, a substrate temperature of approximately 200° C. and a plasma generation frequency of not less than 40 MHz and not more than 100 MHz, a crystalline silicon p-layer 41, a crystalline silicon i-layer 42 and a crystalline silicon n-layer 43 are deposited sequentially as the second cell layer 92 on top of the intermediate contact layer 5. The crystalline silicon p-layer 41 comprises mainly B-doped microcrystalline silicon, and has a thickness of not less than 10 nm and not more than 50 nm. The crystalline silicon i-layer 42 comprises mainly microcrystalline silicon, and has a thickness of not less than 1.2 μm and not more than 3.0 μm. The crystalline silicon n-layer 43 comprises mainly P-doped microcrystalline silicon, and has a thickness of not less than 20 nm and not more than 50 nm.

During formation of the i-layer comprising mainly microcrystalline silicon using a plasma-enhanced CVD method, a distance d between the plasma discharge electrode and the surface of the substrate 1 is preferably not less than 3 mm and not more than 10 mm. If this distance d is less than 3 mm, then the precision of the various structural components within the film deposition chamber required for processing large substrates means that maintaining the distance d at a constant value becomes difficult, which increases the possibility of the electrode getting too close and making the discharge unstable. If the distance d exceeds 10 mm, then achieving a satisfactory deposition rate (of at least 1 nm/s) becomes difficult, and the uniformity of the plasma also deteriorates, causing a deterioration in the quality of the film due to ion impact.

(5) FIG. 2(e)

The substrate 1 is mounted on an X-Y table, and the second harmonic of a laser diode excited YAG laser (532 nm) is irradiated onto the surface of the photovoltaic layer 3, as shown by the arrow in the figure. With the pulse oscillation set to 10 kHz to 20 kHz, the laser power is adjusted so as to achieve a suitable process speed, and laser etching is conducted at a point approximately 100 μm to 150 μm to the side of the laser etching line within the transparent electrode layer 2, so as to form a slot 11. The laser may also be irradiated from the side of the substrate 1, and in this case, because the high vapor pressure generated by the energy absorbed by the amorphous silicon-based first cell layer of the photovoltaic layer 3 can be utilized in etching the photovoltaic layer 3, more stable laser etching processing can be performed. The position of the laser etching line is determined with due consideration of positioning tolerances, so as not to overlap with the previously formed etching line.

(6) FIG. 3(a)

Using a sputtering apparatus, an Ag film and a Ti film are deposited as the back electrode layer 4, under a reduced pressure atmosphere and at a deposition temperature of 150° C. to 200° C. In this embodiment, an Ag film having a thickness of not less than 150 nm and not more than 500 nm, and a highly corrosion-resistant Ti film having a thickness of not less than 10 nm and not more than 20 nm, which acts as a protective film for the Ag film, are stacked in that order. Alternatively, the back electrode layer 4 may be formed as a stacked structure composed of an Ag film having a thickness of 25 nm to 100 nm, and an Al film having a thickness of 15 nm to 500 nm. In order to reduce the contact resistance between the crystalline silicon n-layer 43 and the back electrode layer 4 and improve the reflectance, a GZO (Ga-doped ZnO or Al-doped ZnO) film 6 having a thickness of not less than 50 nm and not more than 100 nm may be deposited as a backside transparent electrode layer between the photovoltaic layer 3 and the back electrode layer 4 using a sputtering apparatus.

(7) FIG. 3(b)

The substrate 1 is mounted on an X-Y table, and the second harmonic of a laser diode excited YAG laser (532 nm) is irradiated through the substrate 1, as shown by the arrow in the figure. The laser light is absorbed by the photovoltaic layer 3, and by utilizing the high gas vapor pressure generated at this point, the back electrode layer 4 is removed by explosive fracture. With the pulse oscillation set to not less than 1 kHz and not more than 10 kHz, the laser power is adjusted so as to achieve a suitable process speed, and laser etching is conducted at a point approximately 250 μm to 400 μm to the side of the laser etching line within the transparent electrode layer 2, so as to form a slot 12.

(8) FIG. 3(c) and FIG. 4(a)

The electric power generation region is then compartmentalized, by using laser etching to remove the effect wherein the serially connected portions at the film edges near the edges of the substrate are prone to short circuits. The substrate 1 is mounted on an X-Y table, and the second harmonic of a laser diode excited YAG laser (532 nm) is irradiated through the substrate 1. The laser light is absorbed by the transparent electrode layer 2 and the photovoltaic layer 3, and by utilizing the high gas vapor pressure generated at this point, the back electrode layer 4 is removed by explosive fracture, and the back electrode layer 4, the photovoltaic layer 3 and the transparent electrode layer 2 are removed. With the pulse oscillation set to not less than 1 kHz and not more than 10 kHz, the laser power is adjusted so as to achieve a suitable process speed, and laser etching is conducted at a point approximately 5 mm to 20 mm from the edge of the substrate 1, so as to form an X-direction insulation slot 15 as illustrated in FIG. 3(c). FIG. 3(c) represents an X-direction cross-sectional view cut along the direction of the series connection of the photovoltaic layer 3, and therefore the location in the figure where the insulation slot 15 is formed should actually appear as a peripheral film removed region 14 in which the back electrode layer 4, the photovoltaic layer 3 and the transparent electrode layer 2 have been removed by film polishing (see FIG. 4(a)), but in order to facilitate description of the processing of the edges of the substrate 1, this location in the figure represents a Y-direction cross-sectional view, so that the formed insulation slot represents the X-direction insulation slot 15. A Y-direction insulation slot need not be provided at this point, because a film surface polishing and removal treatment is conducted on the peripheral film removal regions of the substrate 1 in a later step.

Completing the etching of the insulation slot 15 at a position 5 mm to 15 mm from the edge of the substrate 1 is preferred, as it ensures that the insulation slot 15 is effective in inhibiting external moisture from entering the interior of the solar cell module 7 via the edges of the solar cell panel.

Although the laser light used in the steps until this point has been specified as YAG laser light, light from a YVO4 laser or fiber laser or the like may also be used in a similar manner.

(9) FIG. 4 (a: View from Solar Cell Film Surface Side, b: View from Substrate Side of Light Incident Surface)

In order to ensure favorable adhesion and sealing of a backing sheet 24 via EVA or the like in a subsequent step, the stacked films around the periphery of the substrate 1 (in a peripheral film removal region 14), which tend to be uneven and prone to peeling, are removed to form a peripheral film removed region 14. During removal of the films from a region that is 5 mm to 20 mm from the edge around the entire periphery of the substrate 1, grinding or blast polishing or the like is used to remove the back electrode layer 4, the photovoltaic layer 3 and the transparent electrode layer 2 from a region that is closer to the substrate edge in the X direction than the insulation slot 15 provided in the above step of FIG. 3(c), and closer to the substrate edge in the Y direction than the slot 10 provided near the substrate edge.

Grinding debris or abrasive grains are removed by washing the substrate 1.

(10) FIG. 5(a) (b)

An attachment portion for a terminal box 23 is prepared by providing an open through-window in the backing sheet 24 to expose a collecting plate. A plurality of layers of an insulating material are provided in this open through-window portion in order to prevent external moisture and the like entering the solar cell module.

Processing is conducted so as to enable current collection, using a copper foil, from the series-connected solar cell electric power generation cell at one end, and the solar cell electric power generation cell at the other end, in order to enable electric power to be extracted from the terminal box 23 on the back surface of the solar cell panel. In order to prevent short circuits between the copper foil and the various portions, an insulating sheet that is wider than the width of the copper foil is provided.

Following arrangement of the collecting copper foil and the like at predetermined positions, the entire solar cell module 7 is covered with a sheet of an adhesive filling material such as EVA (ethylene-vinyl acetate copolymer), which is arranged so as not to protrude beyond the substrate 1.

A backing sheet 24 with a superior waterproofing effect is then positioned on top of the EVA. In this embodiment, in order to achieve a superior waterproofing and moisture-proofing effect, the backing sheet 24 is formed as a three-layer structure comprising a PET sheet, an Al foil and another PET sheet.

The structure comprising the components up to and including the backing sheet 24 arranged in predetermined positions is subjected to internal degassing under a reduced pressure atmosphere and under pressing at approximately 150° C. to 160° C. using a laminator, thereby causing cross-linking of the EVA that tightly seals the structure.

(11) FIG. 5(a)

The terminal box 23 is attached to the back of the solar cell module 7 using an adhesive.

(12) FIG. 5(b)

The copper foil and an output cable from the terminal box 23 are connected using solder or the like, and the interior of the terminal box 23 is filled and sealed with a sealant (a potting material). This completes the production of the solar cell panel 50.

(13) FIG. 5(c)

The solar cell panel 50 formed via the steps up to and including FIG. 5(b) is then subjected to an electric power generation test, as well as other tests for evaluating specific performance factors. The electric power generation test is conducted using a solar simulator that emits a standard sunlight of AM 1.5 (1,000 W/m²).

(14) FIG. 5(d)

In tandem with the electric power generation test (FIG. 5(c)), a variety of specific performance factors including the external appearance are evaluated.

### Second Embodiment

In a photovoltaic device according to a second embodiment illustrated in FIG. 9, the intermediate contact layer 5 is composed of a first layer 5a and a second layer 5b stacked in sequence with the first layer 5a disposed nearer the substrate 1. The first layer 5a is a GZO film that contains no nitrogen atoms. The second layer 5b is a GZO film that comprises nitrogen atoms, similar to the intermediate contact layer of the first embodiment.

With the exception of the step of forming the intermediate contact layer 5, the photovoltaic device according to the second embodiment is produced using the same steps as those of the first embodiment.

During formation of the intermediate contact layer of this second embodiment, first, an RF magnetron sputtering apparatus is used to deposit the first layer 5a under conditions including a Ga₂O₃-doped ZnO sintered compact as the target, Ar gas and O₂ gas as the raw material gases, a pressure of 0.13 to 0.67 Pa, RF power of 1.1 to 4.4 W/cm², and a substrate temperature of 120° C. Following deposition of the first layer, N₂ gas is supplied as an additional raw material gas, and the second layer 5b is deposited.

During formation of the nitrogen-containing GZO film that functions as the second layer 5b that contacts the second cell layer 92, provided the deposition conditions are adjusted to ensure that the sheet resistance following exposure to a hydrogen plasma is not less than 1 kΩ/square and not more than 100 kΩ/square, leakage current can be suppressed, and an intermediate contact layer having favorable contact properties can be obtained.

The thickness of the intermediate contact layer 5 of the second embodiment is not less than 20 nm and not more than 100 nm. Because a hydrogen plasma acts most strongly in the vicinity of the exposed surface, the thickness of the second layer 5b is not less than 10 nm and not more than 15 nm.

In the present embodiment, at least one of the first layer 5a and the second layer 5b may comprise a Ga₂O₃-doped compound represented by Zn₁₋ₓMgₓO₂ (0.096≦x≦0.183) as the main component.

In those cases where the first layer 5a and the second layer 5b are formed from the same material, the two layers can be deposited consecutively inside the same deposition chamber. If the first layer 5a and the second layer 5b are formed from different materials, then deposition may be conducted, for example, using a sputtering apparatus with two deposition chambers, wherein a Ga₂O₃-doped ZnO sintered compact and a Ga₂O₃-doped ZnO—MgO mixed target (MgO ratio: 5 to 10 mass %) are used as the targets within the respective chambers.

### EXAMPLES

A tandem solar cell module having the layer structure illustrated in FIG. 1 was formed on a glass substrate. The conditions for each of the layers are listed below.

Transparent electrode layer: F-doped SnO₂ thin film, thickness 800 nm

First cell layer:
p layer: thickness 10 nm
i-layer: thickness 200 nm
n-layer: thickness 30 nm

Intermediate contact layer: nitrogen-containing GZO film (Ga₂O₃: 0.5 mass %), thickness 80 nm

Second cell layer:
layer: thickness 30 nm
i-layer: thickness 1,900 nm
n-layer: thickness 30 nm

Back electrode layer: Ag thin film, thickness 250 nm

The intermediate contact layer was deposited under conditions including a ratio of the N₂ gas flow rate relative to the Ar gas flow rate of 0 to 6%, an O₂ gas flow rate ratio of 1%, a substrate temperature of 120° C., a deposition pressure of 0.2 Pa, and RF power of 4.4 W/cm².

As illustrated in FIG. 3(c), the module structure included three slots (10 to 12) formed in a single connection portion.

FIG. 10 to FIG. 13 illustrate the relationships between the amount of added N₂ gas during deposition of the intermediate contact layer and the performance of the module. In each of FIG. 10 to FIG. 13, the horizontal axis represents the ratio of the N₂ gas flow rate relative to the Ar gas flow rate. The vertical axis represents the short-circuit current in FIG. 10, the open-circuit voltage in FIG. 11, the fill factor in FIG. 12, and the electric power generation efficiency in FIG. 13. The short-circuit current decreased as the amount of added N₂ gas was increased. In contrast, the fill factor exhibited a maximum when the amount of added N₂ gas was 3%. Due to the effect of the fill factor, the electric power generation efficiency increased significantly for amounts of added N₂ gas from 1% to 4% compared with the case where the amount of added N₂ gas was 0% (namely, a GZO film containing no nitrogen).

### REFERENCE SIGNS LIST

1 Substrate
2 Transparent electrode layer
3 Photovoltaic layer
4 Back electrode layer
5 Intermediate contact layer
6 GZO film
7 Solar cell module
31 Amorphous silicon p-layer
32 Amorphous silicon i-layer
33 Amorphous silicon n-layer
41 Crystalline silicon p-layer
42 Crystalline silicon i-layer
43 Crystalline silicon n-layer
91 First cell layer
92 Second cell layer
100 Photovoltaic device

1. A photovoltaic device, comprising a photovoltaic layer comprising two electric power generation cell layers disposed on a substrate, and an intermediate contact layer interposed between the two electric power generation cell layers, wherein
the intermediate contact layer comprises Ga₂O₃-doped ZnO as a main component, and also comprises nitrogen atoms, and
a sheet resistance of the intermediate contact layer following exposure to a hydrogen plasma is not less than 1 kΩ/square and not more than 100 kΩ/square.

2. The photovoltaic device according to claim 1, wherein the intermediate contact layer comprises Ga₂O₃-doped Zn₁₋ₓMgₓO₂ (0.096≦x≦0.183) as a main component.

3. The photovoltaic device according to claim 1, wherein the intermediate contact layer comprises:
a first layer comprising Ga₂O₃-doped ZnO as a main component, and
a second layer provided on a surface of the first layer opposite a substrate-side surface, comprising Ga₂O₃-doped ZnO as a main component, and also comprising nitrogen atoms, wherein
a sheet resistance of the second layer following exposure to a hydrogen plasma is not less than 1 kΩ/square and not more than 100 kΩ/square.

4. The photovoltaic device according to claim 3, wherein the second layer comprises Ga₂O₃-doped Zn₁₋ₓMgₓO₂ (0.096≦x≦0.183) as a main component.

5. The photovoltaic device according to claim 3, wherein a sheet resistance of the second layer following exposure to a hydrogen plasma is not less than 10 kΩ/square and not more than 100 kΩ/square.

6. The photovoltaic device according to claim 2, wherein an MgO ratio within a Ga₂O₃-doped target is not less than 5 mass % and not more than 10 mass %.

7. The photovoltaic device according to claim 3, wherein
a thickness of the intermediate contact layer is within a range from not less than 20 nm to not more than 100 nm, and
a thickness of the second layer is not less than 10 nm and not more than 15 nm.

8. The photovoltaic device according to claim 1, wherein a nitrogen atom concentration within the intermediate contact layer is not less than 0.25 atomic % and not more than 1 atomic %.

9. A process for producing a photovoltaic device comprising a photovoltaic layer comprising two electric power generation cell layers disposed on a substrate, and an intermediate contact layer interposed between the two electric power generation cell layers, wherein
the intermediate contact layer is deposited by sputtering using Ga₂O₃-doped ZnO or Ga₂O₃-doped Zn₁₋ₓMgₓO₂ (0.096≦x≦0.183) as a target, under conditions including a ratio of N₂ gas flow rate relative to Ar gas flow rate of not less than 1% and not more than 4%, and
the photovoltaic layer is deposited using a plasma-enhanced CVD apparatus.

10. The photovoltaic device according to claim 4, wherein a sheet resistance of the second cell layer following exposure to a hydrogen plasma is not less than 10 kΩ/square and not more than 100 kΩ/square.

11. The photovoltaic device according to claim 4, wherein an MgO ratio within a Ga₂O₃-doped target is not less than 5 mass % and not more than 10 mass %.

12. The photovoltaic device according to claim 4, wherein
a thickness of the intermediate contact layer is within a range from not less than 20 nm to not more than 100 nm, and
a thickness of the second layer is not less than 10 nm and not more than 15 nm.

13. The photovoltaic device according to claim 5, wherein
a thickness of the intermediate contact layer is within a range from not less than 20 nm to not more than 100 nm, and
a thickness of the second layer is not less than 10 nm and not more than 15 nm.

14. The photovoltaic device according to claim 10, wherein
a thickness of the intermediate contact layer is within a range from not less than 20 nm to not more than 100 nm, and
a thickness of the second layer is not less than 10 nm and not more than 15 nm.

15. The photovoltaic device according to claim 2, wherein a nitrogen atom concentration within the intermediate contact layer is not less than 0.25 atomic % and not more than 1 atomic %.

16. The photovoltaic device according to claim 3, wherein a nitrogen atom concentration within the intermediate contact layer is not less than 0.25 atomic % and not more than 1 atomic %.

17. The photovoltaic device according to claim 4, wherein a nitrogen atom concentration within the intermediate contact layer is not less than 0.25 atomic % and not more than 1 atomic %.

18. The photovoltaic device according to claim 5, wherein a nitrogen atom concentration within the intermediate contact layer is not less than 0.25 atomic % and not more than 1 atomic %.

19. The photovoltaic device according to claim 10, wherein a nitrogen atom concentration within the intermediate contact layer is not less than 0.25 atomic % and not more than 1 atomic %.
